(19) United States
(12) Patent Application Publication
(10) Pub. No.: US 2026/0060052 A1
(43) Pub. Date: Feb. 26, 2026

(54) SEMICONDUCTOR DEVICE AND MANUFACTURING METHOD FOR SAME

(71) Applicant: Fujian Jinhua Integrated Circuit Co., Ltd., Fujian (CN)

(72) Inventor: Yukihiro NAGAI, Fujian (CN)

(73) Assignee: Fujian Jinhua Integrated Circuit Co., Ltd., Fujian (CN)

(21) Appl. No.: 18/988,906

(22) Filed: Dec. 20, 2024

(30) Foreign Application Priority Data
Aug. 26, 2024 (CN) 202411171392.8

(51) Int. Cl. H01L 21/762; H01L 21/311

(52) U.S. Cl. CPC H10W 10/17; H10P 50/73; H10W 10/0143

(57) ABSTRACT

The present disclosure provides a semiconductor device and a manufacturing method for same. The semiconductor device includes a substrate provided with: a plurality of first active structures, a first isolation structure isolating each of the first active structures, a second active structure, and second isolation structures; where each of the plurality of first active structures extends along a first direction, and the plurality of first active structures include first active segments and second active segments; the second active structure is in direct contact with the second active segments, a plurality of first trenches are opened within the second active structure in an extension direction of the first active structures, and the first trenches are located between the second active segments and an active boundary; and the second isolation structures are filled within the first trenches.

This application claims priority to Chinese Patent Application No. 202411171392.8, filed on August 26, 2024, which is hereby incorporated by reference in its entirety.

### TECHNICAL FIELD

The present disclosure relates to the field of semiconductor technology, and in particular to a semiconductor device and a manufacturing method for same.

### BACKGROUND

With the continuous development and advancement of semiconductor manufacturing technologies, electronic products are in a tendency towards miniaturization and high integration, and feature sizes of various semiconductor devices within the electronic products are constantly being scaled down. The semiconductor devices typically include active regions and isolation regions defining the active regions. As the feature sizes of the semiconductor devices shrink, uniformity of critical dimensions of the active regions degrades.

### SUMMARY

In view of the above issues, embodiments of the present disclosure provide a semiconductor device and a manufacturing method for the semiconductor device, to improve uniformity of critical dimensions of active regions.

According to some embodiments, a first aspect of the present disclosure provides a semiconductor device, comprising a substrate provided with: a plurality of first active structures, a first isolation structure isolating each of the first active structures, a second active structure, and second isolation structures. Where each of the plurality of first active structures extends along a first direction, and the plurality of first active structures comprise first active segments and second active segments; the second active structure is in direct contact with the second active segments, a side of the second active structure facing away from the second active segments is an active boundary, a plurality of first trenches are opened within the second active structure in an extension direction of the first active structures, and the first trenches are located between the second active segments and the active boundary; and the second isolation structures are filled within the first trenches.

In the semiconductor device according to the embodiments of the present disclosure, the second active segments are in contact with the second active structure, the first trenches are disposed within the second active structure, and the first trenches are located in an extension direction of the first active structures, for improvement of uniformity of critical dimensions of the first active structures.

According to some embodiments, a second aspect of the present disclosure provides a manufacturing method for a semiconductor device, comprising: providing a substrate; and forming, on the substrate, a plurality of first active structures, a first isolation structure isolating each of the first active structures, a second active structure and second isolation structures. Each of the plurality of first active structures extends along a first direction, and the plurality of first active structures comprise first active segments and second active segments; the second active structure is in direct contact with the second active segments, a side of the second active structure facing away from the second active segments is an active boundary, a plurality of first trenches are opened within the second active structure in an extension direction of the first active structures, and the first trenches are located between the second active segments and the active boundary; and the second isolation structures are filled within the first trenches.

In the manufacturing method for the semiconductor device according to the embodiment of the present disclosure, a substrate is formed; first active structures, a first isolation structure isolating each of the first active structures, a second active structure and second isolation structures are formed on the substrate. The second active segments are in contact with the second active structure, the first trenches are disposed within the second active structure, and the first trenches are located in an extension direction of the first active structures, for improvement of uniformity of critical dimensions of the first active structures.

### BRIEF DESCRIPTION OF DRAWINGS

FIG. 1 is a schematic diagram of a semiconductor device according to an embodiment of the present disclosure.

FIG. 2 is another schematic diagram of a semiconductor device according to an embodiment of the present disclosure.

FIG. 3 is still another schematic diagram of a semiconductor device according to an embodiment of the present disclosure.

FIG. 4 is a flow diagram of a manufacturing method for a semiconductor device according to an embodiment of the present disclosure.

FIG. 5 is a schematic diagram when a mask layer is formed according to an embodiment of the present disclosure.

FIG. 6 is a cross-sectional diagram when a mask layer is formed according to an embodiment of the present disclosure.

FIG. 7 is a schematic diagram when a trim layer is formed according to an embodiment of the present disclosure.

FIG. 8 is a cross-sectional diagram when a trim layer is formed according to an embodiment of the present disclosure.

FIG. 9 is a cross-sectional diagram when a mask layer is etched using a trim layer as a mask according to an embodiment of the present disclosure.

FIG. 10 is a cross-sectional diagram when a substrate is formed according to an embodiment of the present disclosure.

FIG. 11 is a cross-sectional diagram when filler material is formed according to an embodiment of the present disclosure.

FIG. 12 is a schematic diagram when a first pattern layer is formed according to an embodiment of the present disclosure.

FIG. 13 is a cross-sectional diagram when a first pattern layer is formed according to an embodiment of the present disclosure.

FIG. 14 is a schematic diagram when a second pattern layer is formed according to an embodiment of the present disclosure.

FIG. 15 is a cross-sectional diagram when a second pattern layer is formed according to an embodiment of the present disclosure.

FIG. 16 is a schematic diagram when a first pattern layer is etched using a second pattern layer as a mask according to an embodiment of the present disclosure.

FIG. 17 is a cross-sectional diagram when a first pattern layer is etched using a second pattern layer as a mask according to an embodiment of the present disclosure.

FIG. 18 is a schematic diagram when a third pattern layer is formed according to an embodiment of the present disclosure.

FIG. 19 is a cross-sectional diagram when a third pattern layer is formed according to an embodiment of the present disclosure.

FIG. 20 is a schematic diagram when a first pattern layer is etched using a third pattern layer as a mask according to an embodiment of the present disclosure.

### DESCRIPTION OF EMBODIMENTS

In order to make the foregoing objectives, features and advantages of the embodiments of the present disclosure clearer and more intelligible, the technical solutions of the embodiments of the present disclosure will be described hereunder clearly and comprehensively in conjunction with the accompanying drawings of the embodiments of the present disclosure. Apparently, the described embodiments are merely some of, rather than all of the embodiments of the present disclosure. Based on the embodiments in the present disclosure, all other embodiments obtained by those of ordinary skill in the art without creative efforts shall fall within the protection scope of present disclosure.

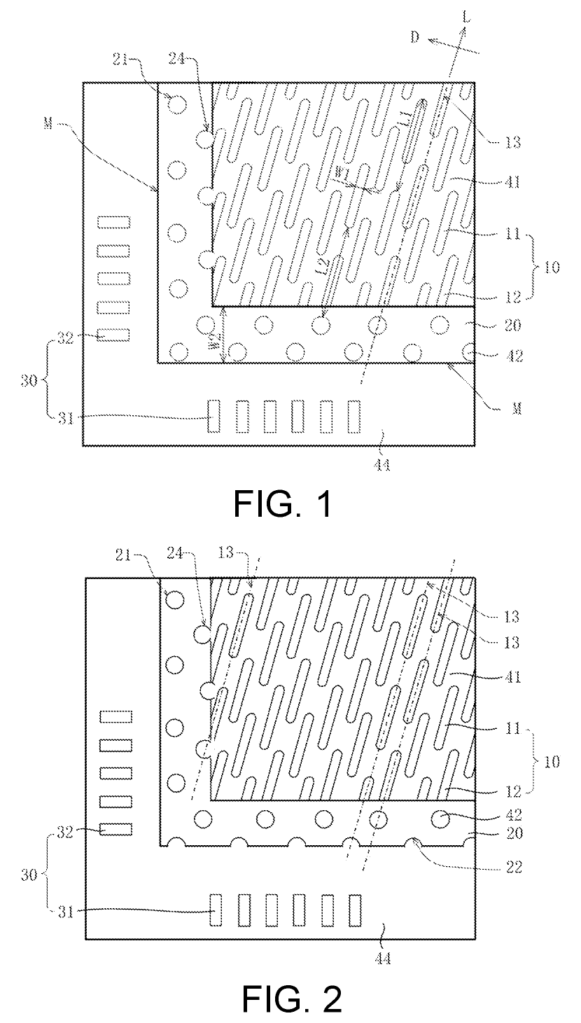

Reference is made to FIG. 1 which is a schematic diagram of a semiconductor device according to an embodiment of the present disclosure. The semiconductor device comprises a substrate which may include, for example, a silicon substrate, a silicon-containing substrate, an epitaxial silicon substrate, a silicon-on-insulator substrate, or a substrate made of other suitable materials.

As shown in FIG. 1, the substrate is provided with first active structures 10, a first isolation structure 41, a second active structure 20 and second isolation structures 42. There are a plurality of first active structures 10, and each of the plurality of first active structures 10 extends along a first direction. The plurality of first active structures 10 are disposed spaced apart along a second direction that intersects the first direction. The first direction is indicated as the direction L in FIG. 1, and the second direction is indicated as the direction D in FIG. 1.

Specifically, the plurality of first active structures 10 are formed into a plurality of rows, where each row has at least two first active structures 10, and the at least two first active structures 10 in a same row are spaced apart along the first direction. For two adjacent rows of first active structures 10 along the second direction, a spacing between two adjacent first active structures 10 in one of the rows faces a first active structure 10 in the other row to increase arrangement density of the first active structures 10, thereby enabling one active structure to be correspondingly connected to at least one word line, and thus improving storage density.

Further reference is made to FIG. 1, the plurality of first active structures 10 comprise first active segments 11 and second active segments 12, where the first active segments 11 extend along the first direction, and the second active segments 12 extend along the first direction. Typically, there are a plurality of first active segments 11 and a plurality of second active segments 12. A spacing is provided between the first active segments 11, between the second active segments 12, and between the first active segments 11 and the second active segments 12. For example, the first isolation structure 41 is disposed to ensure that the plurality of first active structures 10 are not in contact with each other.

The second active segments 12 are located outside the first active segments 11. For example, the second active segments 12 surround the first active segments 11, and the first active segments 11 and the second active segments 12 are disposed spaced apart and arranged in an array. Along the first direction, a second active structure 20 is provided at at least one ends of two ends of the plurality of first active segments 11.

The first active segments 11 are complete segments, and the second active segments 12 are incomplete segments, where a complete segment can be in the shape of an oblong hole, or the like. It should be understood that, along the first direction, the lengths of the first active segments 11 are greater than the lengths of the second active segments 12, and the widths of the plurality of first active segments 11 and the widths of the plurality of second active segments 12 are equal. A contour of a second active segment 12 and a contour of a first active segment 11 with one end being cut off are basically consistent, for example, being coinciding.

The lengths of the plurality of first active segments 11 are equal. Among the plurality of second active segments 12, lengths of some second active segments 12 are equal, and are different from lengths of other second active segments 12. For first active segments 11 and second active segments 12 located in a same row, along the first direction, the spacing between adjacent first active segments 11 equals to the spacing between a first active segment 11 and a second active segment 12 that are adjacent.

Specifically, along the first direction, a first spacing is provided between the same ends of two adjacent first active segments 11. The same ends mean that the positions of the ends in the corresponding first active segments 11 are the same. For example, taking the orientation as shown in FIG. 1 as an example, for two adjacent first active segments 11, a first spacing is provided between an upper end of one first active segment 11 and an upper end of the other first active segment 11, as indicated with L1 in FIG. 1.

Further reference is made to FIG. 1, the first isolation structure 41 isolates each of the first active structures 10. The first isolation structure 41 is, for example, of shallow trench isolation (STI). By means of filling insulating materials such as silicon oxide, silicon nitride or the like between the plurality of first active structures 10, insulation and isolation between the first active structures 10 is achieved. Silicon oxide can be formed through a chemical vapor deposition (CVD) process, with a precursor including tetraethyl orthosilicate.

The second active structure 20 and the second active segments 12 are in direct contact, and can be formed integrally. The second active structure 20 is in no contact with the first active segments 11. The second active structure 20 is located outside the first active segments 11 and the second active segments 12. As an example, the second active structure 20 is in the shape of a strip and located on one sides of the first active segments 11 and the second active segments 12. As another example, the second active structure 20 is in the shape of a ring, such as a square ring, a rectangular ring, or the like, and is sleeved outside the first active segments 11 and the second active segments 12. By means of providing the second active structure 20, the uniformity of the critical dimensions of the first active structures 10 can be improved.

A side of the second active structure 20 facing away from the second active segments 12 is an active boundary, as indicated with M in FIG. 1. In some examples, the active boundary is of a closed pattern, and the first active structures 10, the first active segments 11 and the second active segments 12 are all located within an area enclosed by the active boundary. The dimension of the second active structure 20 along a direction extending away from the first active segments 11 (as indicated with W2 in FIG. 1) is greater than the width of the second active segments 12 (as indicated with W1 in FIG. 1), namely, W2 > W1, and the second active structure 20 is wider.

A plurality of first trenches 21 are opened within the second active structure 20 in an extension direction of the first active structures 10. Namely, the plurality of first trenches 21 which are disposed spaced apart are provided in the second active structure 20, and each of the first trenches 21 is located on one of extension lines 13 of the first active structures 10. One of the extension lines 13 is indicated with a dashed line in FIG. 1, and the extension direction of the extension line 13 is parallel to the first direction.

In addition, the plurality of first trenches 21 are all located between the second active segments 12 and the active boundary, in this way, the plurality of first trenches 21 do not intersect the active boundary. The first trenches 21 can be in the shape of a circle, an ellipse, or the like, and the depths of the first trenches 21 are the same as the depth of the first isolation structure 41. For example, the first trenches 21 and the first isolation structure 41 are formed simultaneously.

Further reference is made to FIG. 1, the second isolation structures 42 are filled within the first trenches 21. For example, the second isolation structures 42 fill and level up the first trenches 21. The second isolation structures 42 comprise insulating materials such as silicon oxide, silicon nitride or the like. The materials of the second isolation structures 42 are the same as the material of the first isolation structure 41, such that the second isolation structures 42 and the first isolation structure 41 can be formed simultaneously, for example, formed by deposition at the same time.

In an embodiment, the second isolation structures 42 comprise a silicon oxide layer and a silicon nitride layer stacked sequentially in a direction away from the wall surfaces of the first trenches 21. Specifically, the first silicon oxide layer covers the sidewalls and bottom walls of the first trenches 21, the silicon nitride layer covers the first silicon oxide layer, and the second silicon oxide layer fills the area enclosed by the silicon nitride layer, thereby, these two silicon oxide layers and the silicon nitride layer fill and level up the first trenches 21.

Further reference is made to FIG. 1, a second spacing is provided between a first active segment 11 adjacent to the second active structure 20 and a second isolation structure 42 which is adjacent to the first active segment 11 along the first direction, as indicated with L2 in FIG. 1. The second spacing and the first spacing are equal, or have a difference that is less than a preset value. The first spacing is the distance between the same ends of the two adjacent first active segments 11 in the first direction, and the preset value equals to 3% of a length of the first isolation structure 41 between the two adjacent first active segments 11 along the first direction. In this way, the second isolation structures 42 and the first isolation structure 41 between the two adjacent first active segments 11 are basically arranged in an array, facilitating manufacturing.

Reference is made to FIG. 2 which is another schematic diagram of a semiconductor device according to an embodiment of the present disclosure. A plurality of second trenches 22 are further opened within the second active structure 20 in the extension direction of the first active structures 10, and the second trenches 22 overlap with the active boundary. The plurality of second trenches 22 are disposed spaced apart, where each of the second trenches 22 is located on one of extension lines 13 of the first active structures 10, and different second trenches 22 correspond to different first active structures 10.

Each of the second trenches 22 has an opening, and openings of the second trenches 22 face away from the first active segments 11. Each of the second trenches 22 is in the shape of a semicircle or a semi-ellipse, or the sidewall of the second trench 22 is in the shape of an inferior arc, a superior arc, or the like. The depths of the second trenches 22 can be the same as the depths of the first trenches 21 to facilitate simultaneous manufacturing of the second trenches 22 and the first trenches 21.

In an embodiment, an area of a second trench 22 is 0.3-0.8 times an area of a first trench 21. In some examples, each of the second trenches 22 is of an equal area, for example, 0.5 times the area of the first trench 21. In some examples, some second trenches 22 have the same area, which is different from the same area that other second trenches 22 have. Specifically, a plurality of second trenches 22 located on one sides (e.g., the lower sides) of the first active segments 11 have the same area, for example, 0.4 times the area of the first trench 21. A plurality of second trenches 22 located on the other sides (e.g., the left sides) of the first active segments 11 have the same area, for example, 0.6 times the area of the first trench 21.

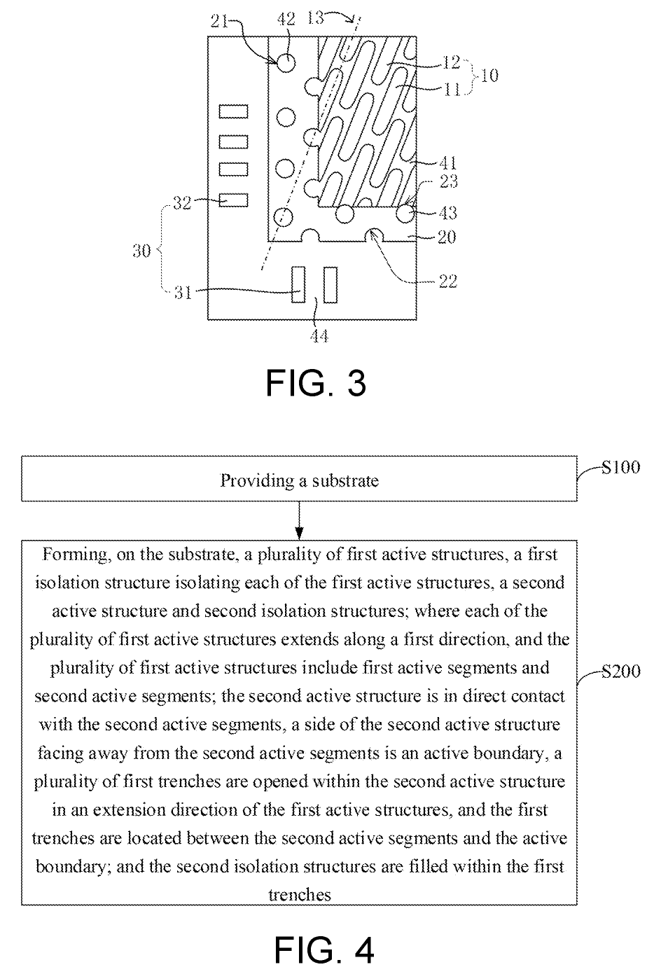

Reference is made to FIG. 3 which is still another schematic diagram of a semiconductor device according to an embodiment of the present disclosure. A plurality of third trenches 23 are further opened within the second active structure 20 in the extension direction of the first active structures 10, where the third trenches 23 are filled with third isolation structures 43, where the third isolation structures 43 are in contact with the second active segments 12. The plurality of third trenches 23 are disposed spaced apart, where each of the third trenches 23 is located on one of extension lines 13 of the first active structures 10, and different third trenches 23 correspond to different first active structures 10. Each of the third trenches 23 is in the shape of a circle.

The third trenches 23 are also partially in contact with the first isolation structure 41, and partially in contact with the second active segments 12. A closed pattern is formed for a third trench 23, which can be a circle, an ellipse or the like. The shape of the third trench 23 can be the same as the shape of the first trench 21, and the area of the third trench 23 can be equal to the area of the first trench 21. The depth of the third trench 23 can be the same as the depth of the first trench 21, to facilitate simultaneous formation of the third trenches 23 and the first trenches 21.

The third isolation structures 43 comprise insulating materials such as silicon oxide, silicon nitride or the like. The materials of the third isolation structures 43 are the same as the materials of the second isolation structures 42, to facilitate simultaneous formation of the third isolation structures 43 and the second isolation structure 42.

With reference to FIG. 2, a plurality of fourth trenches 24 are further opened within the second active structure 20 in the extension direction of the first active structures 10, and the first isolation structure 41 is in contact with and extends into the fourth trenches 24. The plurality of fourth trenches 24 are disposed spaced apart, where each of the fourth trenches 24 is located on one of extension lines 13 of the first active structures 10, and different fourth trenches 24 correspond to different first active structures 10. Each of the fourth trenches 24 is in the shape of a semicircle or a semi-ellipse, or the sidewall of each fourth trench 24 is in the shape of an inferior arc, a superior arc, or the like. The depths of the fourth trenches 24 can be the same as the depths of the first trenches 21 to facilitate simultaneous manufacturing of the fourth trenches 24 and the first trenches 21.

Each of the fourth trenches 24 has an opening, and openings of the fourth trenches 24 face towards the first active segments 11. The first isolation structure 41 extends through the openings of the fourth trenches 24 to be in direct contact with the fourth trenches 24, and to fill and level up the fourth trenches 24. In an embodiment, the fourth trenches 24 are further in contact with the second active segments 12, namely, some of the fourth trenches 24 are located within the second active segments 12.

Further reference is made to FIG. 1, the substrate is further provided with third active structures 30 and a fourth isolation structure 44. The third active structures 30 are disposed spaced apart on a side of the second active structure 20 facing away from the first active structures 10. The third active structures 30 comprise a plurality of third active segments 31. The plurality of third active segments 31 are disposed spaced apart from each other, and disposed spaced apart from the second active structure 20. Each of the third active segments 31 is in the shape of a strip, for example, a rectangular, and arranged side by side on one side of the second active structure 20, for example, the lower side as shown in FIG. 1.

The third active structures 30 further comprise a plurality of fourth active segments 32. The plurality of fourth active segments 32 are disposed spaced apart from each other, and disposed spaced apart from the second active structure 20. Each of the fourth active segments 32 is in the shape of a strip, for example, a rectangular, and arranged side by side on the other side of the second active structure 20, for example, the left side as shown in FIG. 1.

The fourth isolation structure 44 is disposed between the third active structures 30 and the second active structure 20, to isolate the third active structures 30 and the second active structure 20. The fourth isolation structures 44 comprise insulating materials such as silicon oxide, silicon nitride or the like. In some possible examples, the fourth isolation structure 44 can be the same as or different from the first isolation structure 41. When the substrate is provided with the second trenches 22, the fourth isolation structure 44 is further in contact with and filled in the second trenches 22.

The semiconductor device according to the embodiment of the present disclosure comprises a substrate which is provided with the plurality of first active structures 10, the first isolation structure 41, the second active structure 20, and the second isolation structures 42, where the first isolation structure 41 is used to isolate each of the first active structures 10. Each of the plurality of first active structures 10 extends along the first direction. The plurality of first active structures 10 comprise the first active segments 11 and the second active segments 12, and the second active segments 12 are in direct contact with the second active structure 20, such that the second active structure 20 is adjacent to the first active structures 10. The side of the second active structure 20 facing away from the second active segments 12 is the active boundary, the plurality of first trenches 21 are opened within the second active structure 20 in the extension direction of the first active structures 10, the first trenches 21 are located between the second active segments 12 and the active boundary, and the first trenches 21 are filled with the second isolation structures 42. The first trench 21 corresponds to the spacing between a first active segment 11 and a second active segment 12 which are adjacent along the first direction, the uniformity of the critical dimensions of the first active structures 10 can be improved.

Reference is made to FIG. 4 which is a flow diagram of a manufacturing method for a semiconductor device according to an embodiment of the present disclosure. The embodiment of the present disclosure further provides a manufacturing method for a semiconductor device. As shown in FIG. 4, the manufacturing method comprises the following steps.

Step S100: providing a substrate.

The substrate comprises, for example, a silicon substrate, a silicon-containing substrate, an epitaxial silicon substrate, a silicon-on-insulator substrate, or a substrate made of other suitable materials.

Step S200: forming, on the substrate, a plurality of first active structures, a first isolation structure isolating each of the first active structures, a second active structure and second isolation structures; where each of the plurality of first active structures extends along a first direction, and the plurality of first active structures comprise first active segments and second active segments; the second active structure is in direct contact with the second active segments, a side of the second active structure facing away from the second active segments is an active boundary, a plurality of first trenches are opened within the second active structure in an extension direction of the first active structures, and the first trenches are located between the second active segments and the active boundary; and the second isolation structures are filled within the first trenches.

As shown in FIG. 1, the substrate 50 is provided with first active structures 10, a first isolation structure 41, a second active structure 20 and second isolation structures 42. There are a plurality of first active structures 10, and each of the plurality of first active structures 10 extends along a first direction. The plurality of first active structures 10 are disposed spaced apart along a second direction, where the second direction intersects the first direction, for example, being perpendicular to the first direction. The first direction is indicated as the direction L in FIG. 1, and the second direction is indicated as the direction D in FIG. 1.

Specifically, the plurality of first active structures 10 are formed into a plurality of rows, where each row has at least two first active structures 10, and the at least two first active structures 10 in a same row are spaced apart along the first direction. For two adjacent rows of first active structures 10 along the second direction, a spacing between two adjacent first active structures 10 in one of the rows faces a first active structure 10 in the other row to increase arrangement density of the first active structures 10, thereby enabling one active structure to be correspondingly connected to at least one word line, and thus improving storage density.

Further reference is made to FIG. 1, the plurality of first active structures 10 comprise first active segments 11 and second active segments 12. The first active segments 11 extend along the first direction, and the second active segments 12 extend along the first direction. Typically, there are a plurality of first active segments 11 and a plurality of second active segments 12. A spacing is provided between the first active segments 11, between the second active segments 12, and between the first active segments 11 and the second active segments 12. For example, the first isolation structure 41 is disposed to ensure that the plurality of first active structures 10 are not in contact with each other.

The second active segments 12 are located outside the first active segments 11. For example, the second active segments 12 surround the first active segments 11, and the first active segments 11 and the second active segments 12 are disposed spaced apart and arranged in an array. Along the first direction, a second active structure 20 is provided at at least one ends of two ends of the first active segments 11.

The first active segments 11 are complete segments, and the second active segments 12 are incomplete segments, where a complete segment can be in the shape of an oblong hole. It should be understood that, along the first direction, the lengths of the first active segments 11 are greater than the lengths of the second active segments 12, and the widths of the plurality of first active segments 11 and the widths of the plurality of second active segments 12 are equal. A contour of a second active segment 12 and a contour of a first active segment 11 with one end being cut off are basically consistent, for example, being coinciding.

The lengths of the plurality of first active segments 11 are equal. Among the plurality of second active segments 12, lengths of some second active segments 12 are equal, and are different from lengths of other second active segments 12. For first active segments 11 and second active segments 12 located in a same row, along the first direction, the spacing between adjacent first active segments 11 equals to the spacing between a first active segment 11 and a second active segment 12 that are adjacent.

Further reference is made to FIG. 1, the first isolation structure 41 isolates each of the first active structures 10. The first isolation structure 41 is, for example, of shallow trench isolation. By means of filling insulating materials such as silicon oxide, silicon nitride or the like between the plurality of first active structures 10, insulation and isolation between the first active structures 10 is achieved. Silicon oxide can be formed through a chemical vapor deposition process, with a precursor including tetraethyl orthosilicate.

The second active structure 20 and the second active segments 12 are in direct contact, and can be formed integrally. The second active structure 20 is in no contact with the first active segments 11. The second active structure 20 is located outside the first active segments 11 and the second active segments 12. As an example, the second active structure 20 is in the shape of a strip and located on one sides of the first active segments 11 and the second active segments 12. As another example, the second active structure 20 is in the shape of a ring, such as a square ring, a rectangular ring, or the like, and is sleeved outside the first active segments 11 and the second active segments 12. By means of providing the second active structure 20, the uniformity of the critical dimensions of the first active structures 10 can be improved.

A side of the second active structure 20 facing away from the second active segments 12 is an active boundary. The active boundary is of, for example, a closed pattern, and the first active structures 10, the first active segments 11 and the second active segments 12 are all located within an area enclosed by the active boundary. The dimension of the second active structure 20 along a direction extending away from the first active segments 11 is greater than the widths of the second active segments 12, namely, the second active structure 20 is wider.

A plurality of first trenches 21 are opened within the second active structure 20 in an extension direction of the first active structures 10. Namely, the plurality of first trenches 21 which are disposed spaced apart are provided in the second active structure 20, and each of the first trenches 21 is located on one of extension lines 13 of the first active structures 10. The plurality of first trenches 21 are all located between the second active segments 12 and the active boundary, in this way, the plurality of first trenches 21 do not intersect the active boundary. The first trenches 21 can be in the shape of a circle, an ellipse, or the like, and the depths of the first trenches 21 are the same as the height of the first isolation structure 41. For example, the first trenches 21 and the first isolation structure 41 are formed simultaneously.

Further reference is made to FIG. 1, the second isolation structures 42 are filled within the first trenches 21. For example, the second isolation structures 42 fill and level up the first trenches 21. The second isolation structures 42 comprise insulating materials such as silicon oxide, silicon nitride or the like. The materials of the second isolation structures 42 are the same as the material of the first isolation structure 41, such that the second isolation structures 42 and the first isolation structure 41 can be formed simultaneously, for example, formed by deposition at the same time.

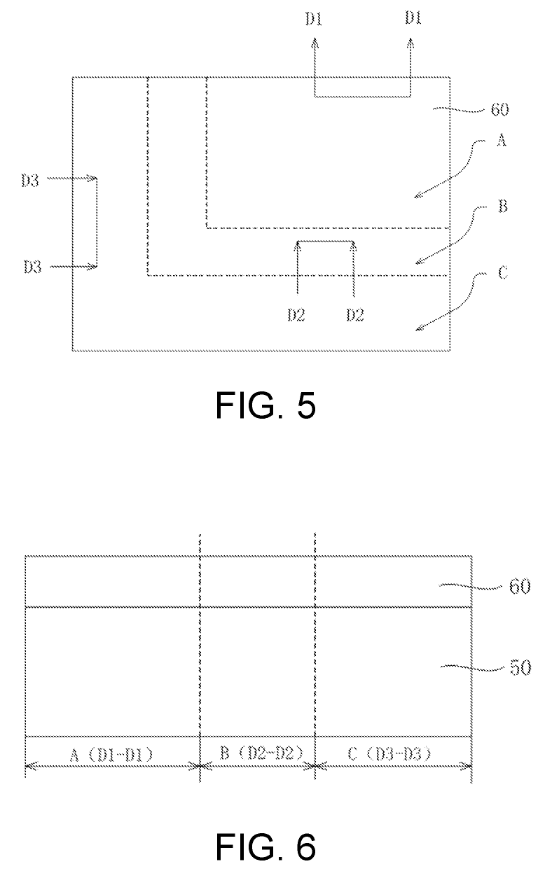

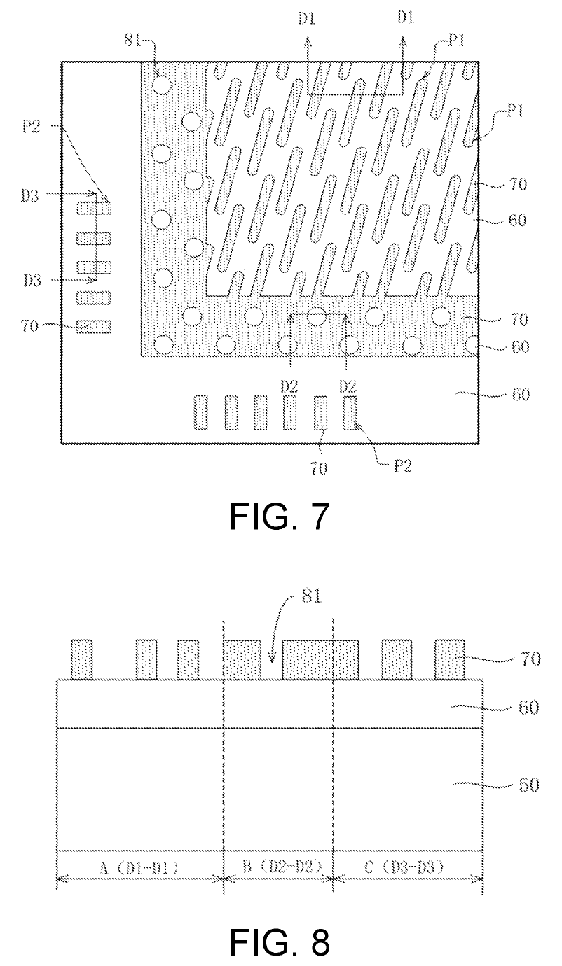

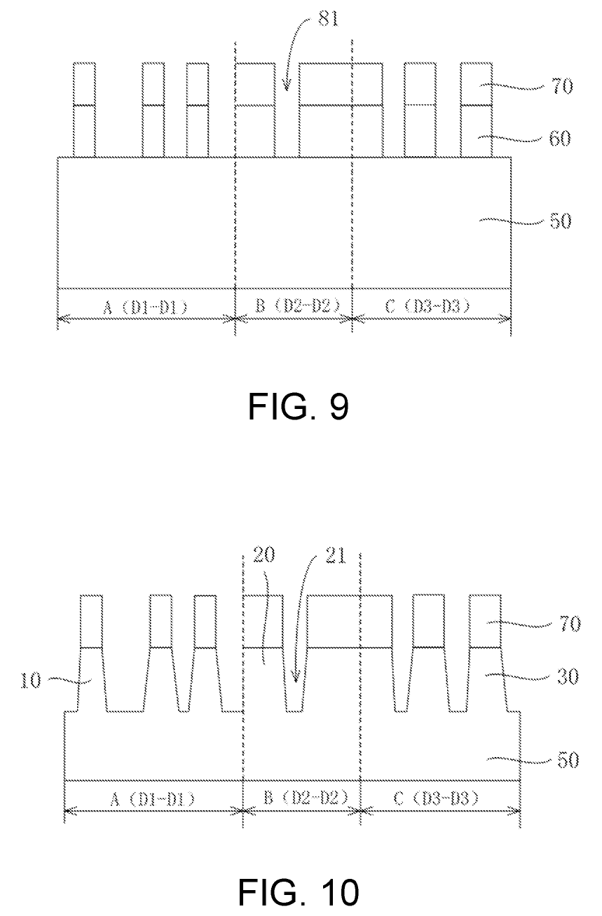

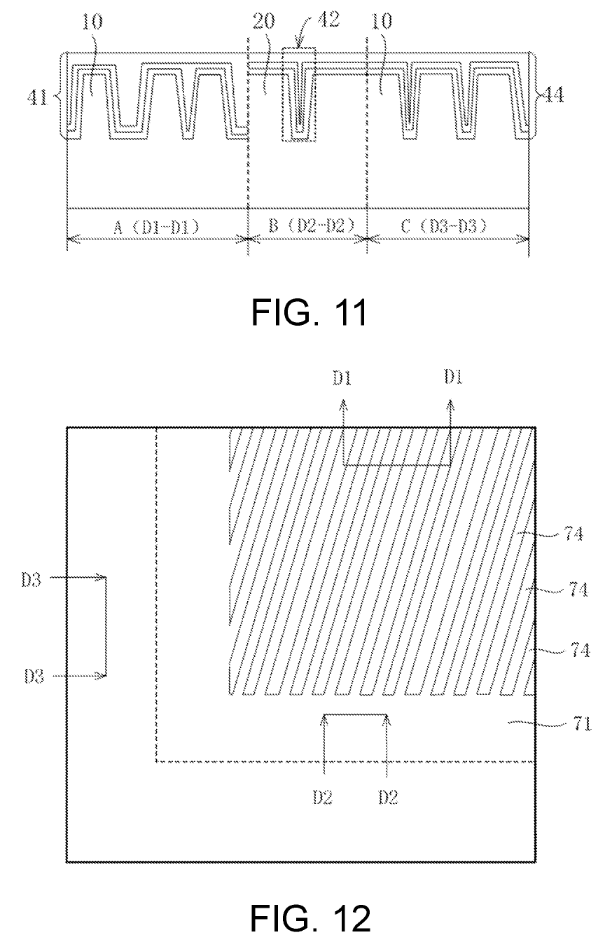

In an embodiment, reference is made to FIG. 5 to FIG. 11, where FIG. 5 is a schematic diagram when a mask layer is formed according to an embodiment of the present disclosure; FIG. 6 is a cross-sectional diagram when a mask layer is formed according to an embodiment of the present disclosure; FIG. 7 is a schematic diagram when a trim layer is formed according to an embodiment of the present disclosure; FIG. 8 is a cross-sectional diagram when a trim layer is formed according to an embodiment of the present disclosure; FIG. 9 is a cross-sectional diagram when a mask layer is etched using a trim layer as a mask according to an embodiment of the present disclosure; FIG. 10 is a cross-sectional diagram when a substrate is formed according to an embodiment of the present disclosure; and FIG. 11 is a cross-sectional diagram when filler material is formed according to an embodiment of the present disclosure.

Forming, on the substrate 50, the plurality of first active structures 10, the first isolation structure 41 isolating each of the first active structures 10, the second active structure 20 and the second isolation structures 42, comprises:

forming a mask layer 60 on the substrate 50, where the substrate comprises a first area, a second area and a third area which are sequentially adjacent, where the second active structure 20 is formed in the second area. As shown in FIG. 5, the first area, the second area, and the third area are divided by dashed lines. The first area is indicated with A in FIG. 5, the second area is indicated with B in FIG. 5, and the third area is indicated with C in FIG. 5. The second area B is located between the first area A and the third area C, and is adjacent to both the first area A and the third area C. For example, the second area B is in a shape of a ring, to the interior of which the first area A is provided and to the exterior of which the third area C is provided. The mask layer 60 can be a single layer or a stacked layer. The mask layer 60 can be a hard mask, for example, including silicon nitride, silicon carbonitride, silicon oxynitride, silicon carbide, metal, organic materials, or the like.

forming a trim layer 70 on the mask layer 60, where the trim layer corresponding to the first area A comprises a plurality of first patterns extending along the first direction, the mask layer 60 is exposed between adjacent first patterns, and a plurality of mask trenches 81 are disposed in the trim layer 70 corresponding to the second area B;

etching the mask layer 60 and the substrate 50 by using the trim layer 70 as a mask, to form the plurality of first active structures 10 disposed spaced apart in the first area A of the substrate 50, and form the second active structure 20 in the second area B of the substrate 50, where the first trenches 21 are provided in the second active structure 20; and

depositing isolation material, where the isolation material between the first active structures 10 forms the first isolation structure 41, and the isolation material in the first trenches 21 forms the second isolation structures 42.

As shown in FIG. 7 and FIG. 8, the trim layer 70 is located on the side of the mask layer 60 facing away from the substrate 50. The trim layer corresponding to the first area comprises a plurality of first patterns as indicated with P1 in FIG. 7. The plurality of first patterns are spaced apart from each other and extend along the first direction, and the mask layer 60 is exposed between the plurality of first patterns. A plurality of mask trenches 81 are disposed in the trim layer 70 corresponding to the second area, where the plurality of mask trenches 81 are disposed spaced apart and the mask layer 60 is exposed. A mask trench 81 can be of a closed pattern which can be a circle or an ellipse.

As shown in FIG. 9 and FIG. 10, the trim layer 70 is used as a mask, to etch the mask layer 60 and the substrate 50, such that the exposed mask layer 60 and the corresponding substrate 50 are removed. The plurality of first active structures 10 disposed spaced apart are formed in the first area A of the substrate 50, and the second active structure 20 is formed in the second area B of the substrate 50, where some of the first active structures 10 are in direct contact with the second active structure 20, and the first trenches 21 are provided in the second active structure 20.

As shown in FIG. 10 and FIG. 11, isolation material is deposited between the first active structures 10 and in the first trenches 21, where the isolation material between the first active structures 10 forms the first isolation structure 41, and the isolation material in the first trenches 21 forms the second isolation structures 42. The second isolation structures 42 fill and level up the first trenches 21, for example, the first isolation structure 41, the second isolation structures 42, the first active structures 10 and the second active structure 20 can be flush with each other.

In an example, the trim layer 70 corresponding to the third area comprises a plurality of third patterns P2, where the plurality of third patterns P2 are disposed spaced apart, and the mask layer 60 is exposed between the plurality of third patterns P2. The plurality of third patterns P2 are located on different sides of the trim layer 70 corresponding to the second area. When the trim layer 70 is used as a mask to etch the mask layer 60 and the substrate 50, a plurality of third active structures 30 are formed in the third area of the substrate 50, where the plurality of third active structures 30 are disposed spaced apart. When the isolation material is deposited, the isolation material is also filled between the third active structures 30 and the second active structure 20, and between the third active structures 30, forming the third isolation structures 43.

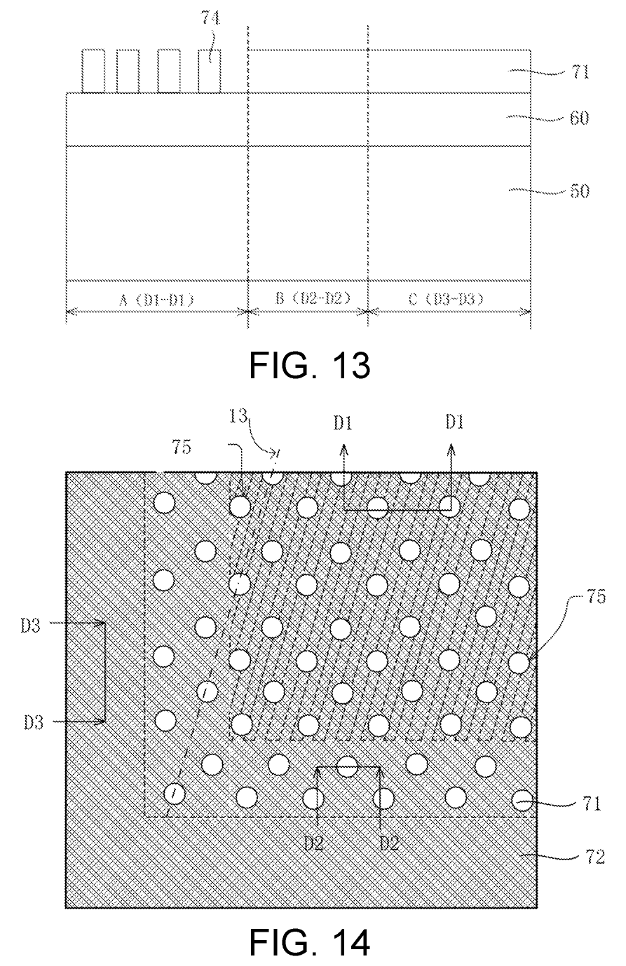

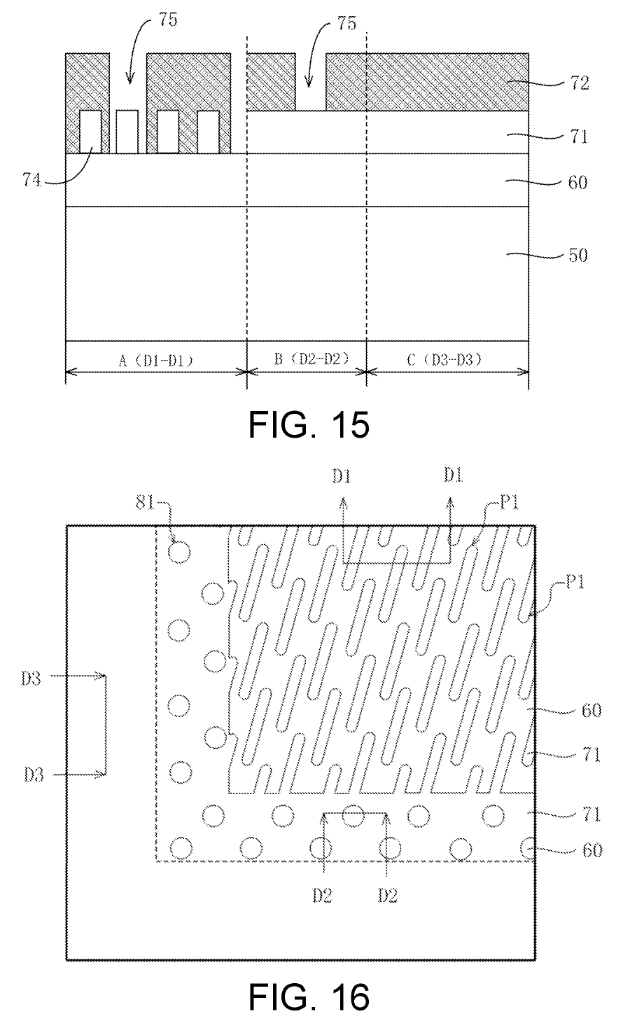

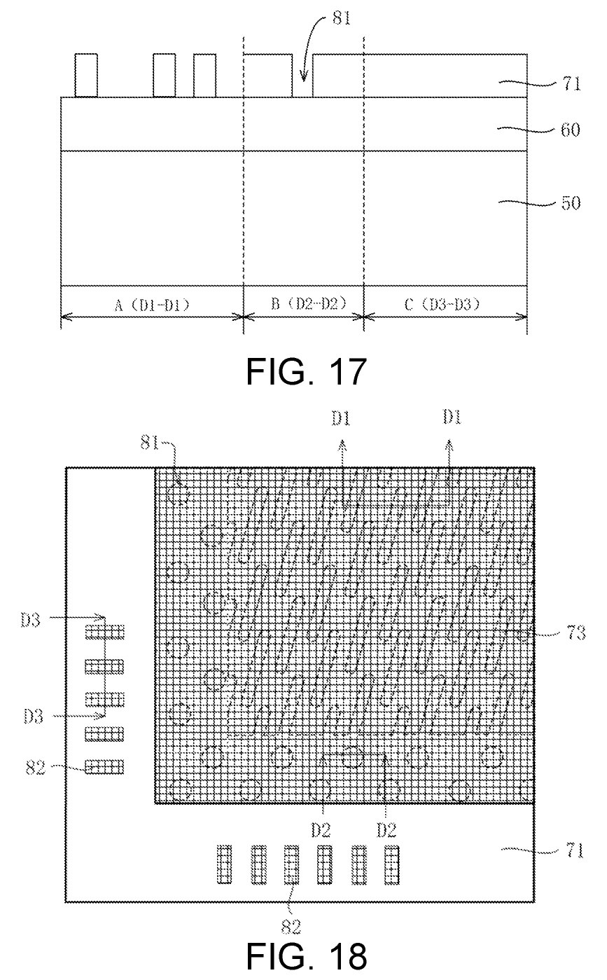

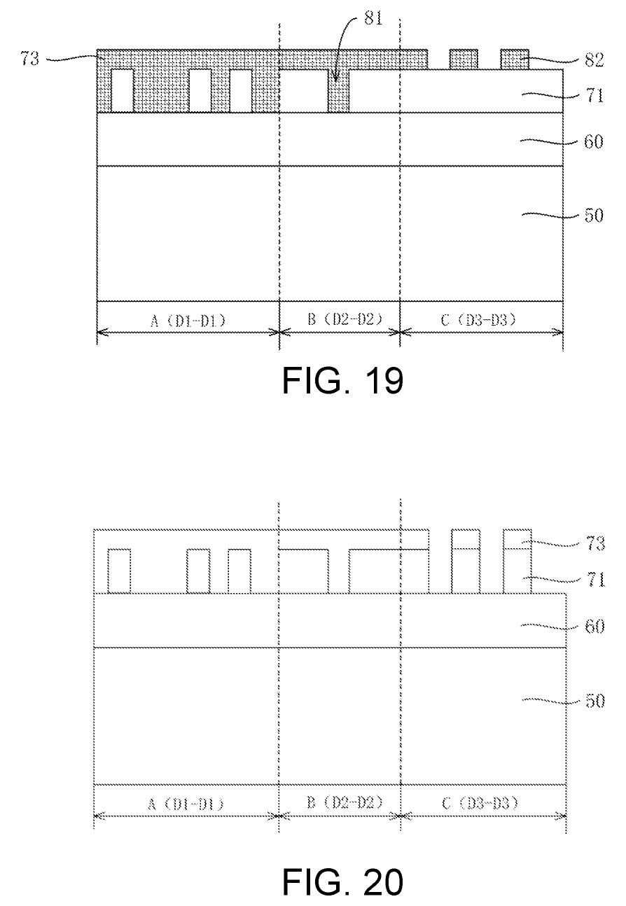

In some possible implementations, reference is made to FIG. 12 to FIG. 20, where FIG. 12 is a schematic diagram when a first pattern layer is formed according to an embodiment of the present disclosure; FIG. 13 is a cross-sectional diagram when a first pattern layer is formed according to an embodiment of the present disclosure; FIG. 14 is a schematic diagram when a second pattern layer is formed according to an embodiment of the present disclosure; FIG. 15 is a cross-sectional diagram when a second pattern layer is formed according to an embodiment of the present disclosure; FIG. 16 is a schematic diagram when a first pattern layer is etched using a second pattern layer as a mask according to an embodiment of the present disclosure; FIG. 17 is a cross-sectional diagram when a first pattern layer is etched using a second pattern layer as a mask according to an embodiment of the present disclosure; FIG. 18 is a schematic diagram when a third pattern layer is formed according to an embodiment of the present disclosure; FIG. 19 is a cross-sectional diagram when a third pattern layer is formed according to an embodiment of the present disclosure; and FIG. 20 is a schematic diagram when a first pattern layer is etched using a third pattern layer as a mask according to an embodiment of the present disclosure.

Forming the trim layer 70 on the mask layer 60 comprises:

forming a first pattern layer 71 on the mask layer 60, where the first pattern layer 71 corresponding to the first area comprises a plurality of first mask strips 74 disposed spaced apart, the mask layer 60 is exposed between adjacent first mask strips 74, and the first pattern layer 71 corresponding to the second area covers the mask layer 60. As shown in FIG. 12 and FIG. 13, the first pattern layer 71 may include spin-on carbon, amorphous carbon, silicon nitride, silicon carbide, silicon oxynitride, polysilicon, or a combination thereof, and the material of the first pattern layer 71 is different from the material of the mask layer 60. The first mask strips 74 extend along the first direction and are in contact with the first pattern layer 71 corresponding to the second area.

Forming a second pattern layer 72 on the first pattern layer 71, where the second pattern layer 72 corresponding to the first area and the second area is provided with a plurality of holes 75 disposed spaced apart, the holes 75 face the first mask strips 74 or are located on extension lines 13 of the first mask strips 74, and the second pattern layer 72 corresponding to the third area covers the first pattern layer 71.

As shown in FIG. 14 and FIG. 15, the second pattern layer 72 is filled between adjacent first mask strips 74, and further covers the first mask strips 74 and the first pattern layer 71 corresponding to the second area and the third area. The second pattern layer 72 may include spin-on carbon, amorphous carbon, silicon nitride, silicon carbide, silicon oxynitride, polysilicon, or a combination thereof, and the material of the second pattern layer 72 is different from the material of the first mask layer 60. The holes 75 corresponding to the first area expose the first mask strips 74, and the holes 75 located on the extension lines 13 of the first mask strips 74 expose the first pattern layer 71.

Etching the first pattern layer 71 by using the second pattern layer 72 as a mask, to separate the first mask strips 74 into the first patterns P1 and form the mask trenches 81 in the first pattern layer 71 corresponding to the second area. As shown in FIG. 15, FIG. 16 and FIG. 17, using the second pattern layer 72 as a mask, the exposed first pattern layer 71 is etched and removed to separate the first mask strips 74 into a plurality of first patterns P1, and the mask trenches 81 are formed in the first pattern layer 71 corresponding to the second area, where the mask trenches 81 expose the mask layer 60.

In other implementations, the first pattern layer 71 is formed on the mask layer 60, as shown in FIG. 12 and FIG. 13, the first pattern layer 71 corresponding to the third area further covers the mask layer 60. The second pattern layer 72 is formed on the first pattern layer 71, as shown in FIG. 14 and FIG. 15, the second pattern layer 72 corresponding to the third area covers the first pattern layer 71.The second pattern layer 72 is used as a mask, to etch the first pattern layer 71, as shown in FIG. 16 and FIG. 17, the first pattern layer 71 corresponding to the third area covers the mask layer 60. In the foregoing implementations, the mask layer 60 corresponding to the third area is not etched.

In another embodiment, as shown in FIG. 17 to FIG. 20, after etching the first pattern layer 71 by using the second pattern layer 72 as a mask, as shown in FIG. 17, it further comprises: removing the second pattern layer 72 to expose the first pattern layer 71. As shown in FIG. 18 and FIG. 19, a third pattern layer 73 is formed, where the third pattern layer 73 corresponding to the first area and the second area covers the first pattern layer 71, the third pattern layer 73 corresponding to the third area comprises a plurality of second mask strips 82 disposed spaced apart, and the second mask strips 82 and the mask trenches 81 are disposed in misaligned arrangement. The third pattern layer 73 can be a single layer or a stacked layer. As shown in FIG. 20, the third pattern layer 73 is used as a mask, to etch the first pattern layer 71, where the third patterns P2 are formed in the first pattern layer 71 corresponding to the third area. The third pattern layer 73 is removed to expose the first pattern layer 71, with the remaining first pattern layer 71 forming the trimming layer 70.

In this way, as shown in FIG. 9 and FIG.10, when the mask layer 60 and the substrate 50 are etched using the trim layer 70 as a mask, the first active structures 10 spaced apart are formed in the first area of the substrate 50, the second active structure 20 and the first trenches 21 are formed in the second area of the substrate 50, and the third active structures 30 spaced apart are formed in the third area of the substrate 50.

The manufacturing method for a semiconductor device according to the embodiment of the present disclosure comprises: providing a substrate 50; forming, on the substrate 50, a plurality of first active structures 10, a first isolation structure 41 isolating each of the first active structures 10, a second active structure 20 and second isolation structures 42. Each of the plurality of first active structures 10 extends along a first direction, and the plurality of first active structures 10 comprises first active segments 11 and second active segments 12. The second active structure 20 is in direct contact with the second active segments 12, a side of the second active structure 20 facing away from the second active segments 12 is an active boundary, a plurality of first trenches 21 are opened within the second active structure 20 in an extension direction of the first active structures 10, and the first trenches 21 are located between the second active segments 12 and the active boundary. The second isolation structures 42 are filled within the first trenches 21. The substrate 50 is provided with the plurality of first active structures 10, the first isolation structure 41, the second active structure 20 and the second isolation structures 42, where the first isolation structure 41 is used to isolate each of the first active structures 10. Each of the plurality of first active structures 10 extends along the first direction. The plurality of first active structures 10 comprise the first active segments 11 and the second active segments 12, and the second active segments 12 are in direct contact with the second active structure 20, such that the second active structure 20 is adjacent to the first active structures 10. The side of the second active structure 20 facing away from the second active segments 12 is the active boundary, the plurality of first trenches 21 are opened within the second active structure 20 in the extension direction of the first active structures 10, the first trenches 21 are located between the second active segments 12 and the active boundary, and the first trenches 21 are filled with the second isolation structures 42. The first trenches 21 correspond to the spacing between a first active segment 11 and a second active segment 12 which are adjacent along the first direction, the uniformity of the critical dimensions of the first active structures 10 can be improved.

The various embodiments or implementations in the present specification are described in a progressive manner, where each embodiment focuses on the differences from other embodiments, and cross reference can be made to the embodiments for the same or similar parts therebetween. The description of reference terms such as “an implementation”, “some implementations”, “illustrative implementations”, “examples”, “specific examples”, or “some examples” refers to the specific features, structures, materials, or characteristics described in conjunction with the implementations or examples being included in at least one implementation or example of the present disclosure. In the present specification, schematic representations of the foregoing terms do not necessarily refer to the same implementations or examples. Moreover, the specific features, structures, materials, or characteristics described can be combined in any one or more of the implementations or examples in a suitable manner.

Finally, it should be noted that the above embodiments are merely used to explain the technical solutions of the present disclosure, but are not intended to limit the present disclosure. Although the present disclosure has been described in detail with reference to the foregoing embodiments, those ordinarily skilled in the art should understand that modifications can be made to the technical solutions recorded in the foregoing embodiments, or some or all of the technical features thereof may be substituted by their equivalents, and such modifications or substitutions do not cause the nature of the corresponding technical solutions to deviate from the scope of the technical solutions of the embodiments of the present disclosure.

What is claimed is:

1. A semiconductor device, comprising a substrate provided with: a plurality of first active structures, a first isolation structure isolating each of the first active structures, a second active structure, and second isolation structures;
wherein each of the plurality of first active structures extends along a first direction, and the plurality of first active structures comprise first active segments and second active segments;
the second active structure is in direct contact with the second active segments, a side of the second active structure facing away from the second active segments is an active boundary, a plurality of first trenches are opened within the second active structure in an extension direction of the first active structures, and the first trenches are located between the second active segments and the active boundary; and
the second isolation structures are filled within the first trenches.

2. The semiconductor device according to claim 1, wherein, along the first direction, a first spacing is provided between same ends of two adjacent first active segments; a second spacing is provided between one of the first active segments that is adjacent to the second active structure and one of the second isolation structures that is adjacent to the first active segment along the first direction, and the second spacing and the first spacing are equal or have a difference that is less than a preset value.

3. The semiconductor device according to claim 2, wherein the preset value equals to 3% of a length of the first isolation structure between the two adjacent first active segments along the first direction.

4. The semiconductor device according to claim 1, wherein a plurality of second trenches are further opened within the second active structure in the extension direction of the first active structures, and the second trenches overlap with the active boundary.

5. The semiconductor device according to claim 4, wherein an area of the second trench is 0.3-0.8 times an area of the first trench.

6. The semiconductor device according to claim 1, wherein a plurality of third trenches are further opened within the second active structure in the extension direction of the first active structures, wherein the third trenches are filled with third isolation structures, wherein the third isolation structures are in contact with the second active segments.

7. The semiconductor device according to claim 1, wherein a plurality of fourth trenches are further opened within the second active structure in the extension direction of the first active structures, and the first isolation structure is in contact with and extends into the fourth trenches.

8. The semiconductor device according to claim 1, wherein the second active structure surrounds the first active structures and is spaced apart from the first active segments.

9. The semiconductor device according to claim 1, wherein the first active segments and the second active segments are disposed spaced apart and arranged in an array.

10. The semiconductor device according to claim 1, wherein the substrate is further provided with:
third active structures, which are disposed spaced apart on a side of the second active structure facing away from the first active structures; and a fourth isolation structure, which is disposed between the third active structures and the second active structure.

11. A manufacturing method for a semiconductor device, comprising:
providing a substrate; and
forming, on the substrate, a plurality of first active structures, a first isolation structure isolating each of the first active structures, a second active structure, and second isolation structures;
wherein each of the plurality of first active structures extends along a first direction, and the plurality of first active structures comprise first active segments and second active segments;
the second active structure is in direct contact with the second active segments, a side of the second active structure facing away from the second active segments is an active boundary, a plurality of first trenches are opened within the second active structure in an extension direction of the first active structures, and the first trenches are located between the second active segments and the active boundary; and
the second isolation structures are filled within the first trenches.

12. The manufacturing method according to claim 11, wherein the forming, on the substrate, the plurality of first active structures, the first isolation structure isolating each of the first active structures, the second active structure, and the second isolation structures comprises:
forming a mask layer on the substrate, wherein the substrate comprises a first area, a second area and a third area which are sequentially adjacent, and the second active structure is located in the second area; forming a trim layer on the mask layer, wherein the trim layer corresponding to the first area comprises a plurality of first patterns extending along the first direction, the mask layer is exposed between adjacent first patterns, and a plurality of mask trenches are disposed in the trim layer corresponding to the second area; etching the mask layer and the substrate by using the trim layer as a mask, to form the plurality of first active structures disposed spaced apart in the first area of the substrate, and form the second active structure in the second area of the substrate, wherein the first trenches are provided in the second active structure; and depositing isolation material, wherein the isolation material between the first active structures forms the first isolation structure, and the isolation material in the first trenches forms the second isolation structures.

13. The manufacturing method according to claim 12, wherein the forming the trim layer on the mask layer comprises:
forming a first pattern layer on the mask layer, wherein the first pattern layer corresponding to the first area comprises a plurality of first mask strips disposed spaced apart, the mask layer is exposed between adjacent first mask strips, and the first pattern layer corresponding to the second area covers the mask layer;
forming a second pattern layer on the first pattern layer, wherein the second pattern layer corresponding to the first area and the second area is provided with a plurality of holes disposed spaced apart, the holes face the first mask strips or are located on extension lines of the first mask strips, and the second pattern layer corresponding to the third area covers the first pattern layer; etching the first pattern layer by using the second pattern layer as a mask, to separate the first mask strips into the first patterns and form the mask trenches in the first pattern layer corresponding to the second area.

14. The manufacturing method according to claim 11, wherein, along the first direction, a first spacing is provided between same ends of two adjacent first active segments;
a second spacing is provided between one of the first active segments that is adjacent to the second active structure and one of the second isolation structures that is adjacent to the first active segment along the first direction, and the second spacing and the first spacing are equal or have a difference that is less than a preset value.

15. The manufacturing method according to claim 14, wherein the preset value equals to 3% of a length of the first isolation structure between the two adjacent first active segments along the first direction.

16. The manufacturing method according to claim 11, wherein a plurality of second trenches are further opened within the second active structure in the extension direction of the first active structures, and the second trenches overlap with the active boundary.

17. The manufacturing method according to claim 16, wherein an area of the second trench is 0.3-0.8 times an area of the first trench.

18. The manufacturing method according to claim 14, wherein a plurality of third trenches are further opened within the second active structure in the extension direction of the first active structures, wherein the third trenches are filled with third isolation structures, wherein the third isolation structures are in contact with the second active segments.

19. The manufacturing method according to claim 14, wherein a plurality of fourth trenches are further opened within the second active structure in the extension direction of the first active structures, and the first isolation structure is in contact with and extends into the fourth trenches.

20. The manufacturing method according to claim 14, wherein the second active structure surrounds the first active structures and is spaced apart from the first active segments.
